(19) United States
(12) Patent Application Publication
(10) Pub. No.: US 2012/0021577 A1
(43) Pub. Date: Jan. 26, 2012

(54) GATE TRENCH CONDUCTOR FILL

(76) Inventor: ROBERT J. PURTELL, West Jordan, UT (US)

(21) Appl. No.: 13/168,270

(22) Filed: Jun. 24, 2011

Related U.S. Application Data
(60) Provisional application No. 61/366,372, filed on Jul. 21, 2010.

(51) Int. Cl. H01L 21/336; H01L 21/283

(52) U.S. Cl. 438/270; 438/589; 257/E21.159; 257/E21.41

(57) ABSTRACT

Semiconductor devices and methods for making such devices are described. The semiconductor devices contain a substrate with a trench in an upper portion thereof, a gate insulating layer on a sidewall and bottom of the trench, and a conductive gate of an amorphous silicon or polysilicon material on the gate oxide layer. The amorphous silicon or polysilicon layer can be doped with nitrogen, as well as B and/or P dopants, which have been activated by microwaves. The devices can be made by providing a trench in the upper surface of a semiconductor substrate, forming a gate insulating layer on the trench sidewall and bottom, and depositing a doped amorphous silicon or polysilicon layer on the gate insulating layer, and then activating the deposited amorphous silicon or polysilicon layer at low temperatures using microwaves. The resulting polysilicon or amorphous silicon layer contains fewer voids resulting from Si grain movement. Other embodiments are described.

### CROSS-REFERENCE TO RELATED APPLICATION

This patent application claims priority of U.S. Provisional Application Ser. No. 61/366,372, filed on Jul. 21, 2010, the entire disclosure of which is hereby incorporated by reference.

### FIELD

This application relates generally to semiconductor devices and methods for making such devices. More specifically, this application describes semiconductor devices containing gate trench structures where the gate conductor has been formed from a conductive silicon layer containing microwave-activated dopants.

### BACKGROUND

Semiconductor devices containing integrated circuits (ICs) or discrete devices are used in a wide variety of electronic apparatus. The IC devices (or chips, or discrete devices) comprise a miniaturized electronic circuit that has been manufactured in the surface of a substrate of semiconductor material. The circuits are composed of many overlapping layers, including layers containing dopants that can be diffused into the substrate (called diffusion layers) or ions that are implanted (implant layers) into the substrate. Other layers are conductors (polysilicon or metal layers) or connections between the conducting layers (via or contact layers). IC devices or discrete devices can be fabricated in a layer-by-layer process that uses a combination of many steps, including growing layers, imaging, deposition, etching, doping and cleaning Silicon wafers are typically used as the substrate and photolithography is used to mark different areas of the substrate to be doped or to deposit and define polysilicon, insulators, or metal layers.

One type of semiconductor device, a metal oxide silicon field effect transistor (MOSFET) device, can be widely used in numerous electronic apparatus, including automotive electronics, disk drives and power supplies. Some MOSFET devices can be formed in a trench that has been created in the substrate. One feature making the trench configuration attractive is that the current flows vertically through the channel of the MOSFET. This permits a higher cell and/or current channel densities than other MOSFETs where the current flows horizontally through the channel and then vertically through the drain. The trench MOSFET devices contain a gate structure formed in the trench where the gate structure contains a gate insulating layer on the sidewall and bottom of the trench (i.e., adjacent the substrate material) with a conductive layer that has been formed on the gate insulating layer.

### SUMMARY

This application describes semiconductor devices and methods for making such devices. The semiconductor devices contain a substrate with a trench in an upper portion thereof, a gate insulating layer on a sidewall and bottom of the trench, and a conductive gate of an amorphous silicon or polysilicon material on the gate oxide layer. The amorphous silicon or polysilicon layer can be doped with nitrogen, as well as B and/or P dopants, which have been activated by microwaves. The devices can be made by providing a trench in the upper surface of a semiconductor substrate, forming a gate insulating layer on the trench sidewall and bottom, and depositing a doped amorphous silicon or polysilicon layer on the gate insulating layer, and then activating the deposited amorphous silicon or polysilicon layer at low temperatures using microwaves. The resulting polysilicon or amorphous silicon layer contains fewer voids resulting from reduced Si grain movement during low temperature processing.

### BRIEF DESCRIPTION OF THE DRAWINGS

The following description can be better understood in light of the Figures, in which:

FIG. 1 shows some embodiments of methods for making a semiconductor structure containing a substrate and an epitaxial (or “epi”) layer with a mask on the upper surface of the epitaxial layer;

FIG. 2 depicts some embodiments of methods for making a semiconductor structure containing a trench formed in the epitaxial layer;

FIG. 3 depicts some embodiments of methods for making a semiconductor structure containing a gate insulating layer in the trench;

FIG. 4 shows some embodiments of methods for making a semiconductor structure containing a conductive Si gate formed on the gate insulating layer;

FIG. 5 shows some embodiments of methods for making a semiconductor structure containing an insulation cap on the gate; and

FIG. 6 shows some embodiments of methods for making a semiconductor structure containing a trench MOSFET device.

The Figures illustrate specific aspects of the semiconductor devices and methods for making such devices. Together with the following description, the Figures demonstrate and explain the principles of the methods and structures produced through these methods. In the drawings, the thickness of layers and regions are exaggerated for clarity. The same reference numerals in different drawings represent the same element, and thus their descriptions will not be repeated. As the terms on, attached to, or coupled to are used herein, one object (e.g., a material, a layer, a substrate, etc.) can be on, attached to, or coupled to another object regardless of whether the one object is directly on, attached, or coupled to the other object or there are one or more intervening objects between the one object and the other object. Also, directions (e.g., above, below, top, bottom, side, up, down, under, over, upper, lower, horizontal, vertical, “x,” “y,” “z,” etc.), if provided, are relative and provided solely by way of example and for ease of illustration and discussion and not by way of limitation. In addition, where reference is made to a list of elements (e.g., elements a, b, c), such reference is intended to include any one of the listed elements by itself, any combination of less than all of the listed elements, and/or a combination of all of the listed elements.

### DETAILED DESCRIPTION

The following description supplies specific details in order to provide a thorough understanding. Nevertheless, the skilled artisan would understand that the semiconductor devices and associated methods of making and using the devices can be implemented and used without employing these specific details. Indeed, the semiconductor devices and associated methods can be placed into practice by modifying the illustrated devices and methods and can be used in conjunction with any other apparatus and techniques conventionally used in the industry. For example, while the description refers to U-MOS (U-shaped MOSFET) semiconductor devices, it could be modified for any other types of semiconductor devices containing gate structures formed in a trench such as CMOS or LDMOS.

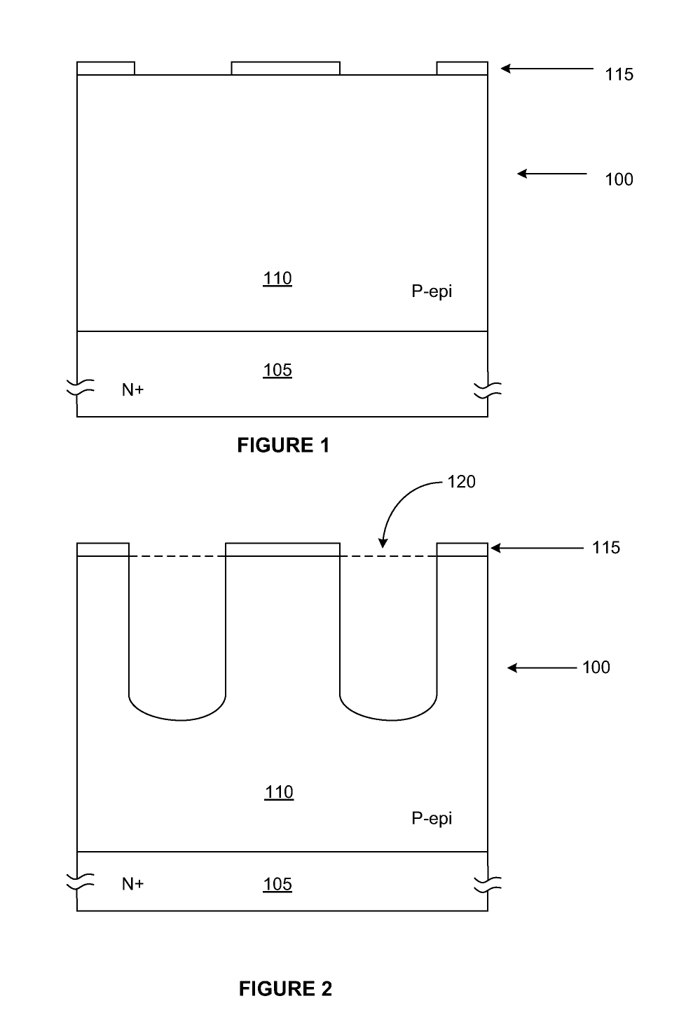

Some embodiments of the semiconductor devices and methods for making such devices are illustrated in FIGS. 1-6 and described herein. The methods begin in these embodiments, as depicted in FIG. 1, when a semiconductor substrate 105 is first provided as part of the semiconductor structure 100. Any substrate known in the art can be used in the invention. Suitable substrates include silicon wafers, epitaxial Si layers, bonded wafers such as used in silicon-on-insulator (SOI) technologies, and/or amorphous silicon layers, all of which may be doped or undoped. Also, any other semiconducting material used for electronic devices can be used, including Ge, SiGe, GaN, and/or any pure or compound semiconductors, such as III-V or II-VIs and their variants. In some embodiments, as shown in FIG. 1, the substrate 105 comprises silicon that is optionally heavily doped with any n-type dopant.

Where the substrate 105 comprises silicon, it can contain one or more epitaxial (“epi”) Si layers (individually or collectively depicted as epitaxial layer 110) located on an upper surface thereof. The epitaxial layer(s) 110 can be provided using any known process in the art, including any known epitaxial deposition process. In some configurations, the epitaxial layer(s) can be lightly doped with a p-type dopant, as shown in FIG. 1.

Next, as shown in FIG. 2, a trench 120 can be formed in the epitaxial layer 110 (and optionally the substrate 105). The bottom of the trench 120 can reach any depth in the epitaxial layer 110 or the substrate 105. The trench 120 can be formed by any known process. In some embodiments, a mask 115 can be formed on the upper surface of the epitaxial layer 110 by depositing a layer of the desired mask material and then patterning it using a photolithography and etch process so the desired pattern of the mask 115 is formed.

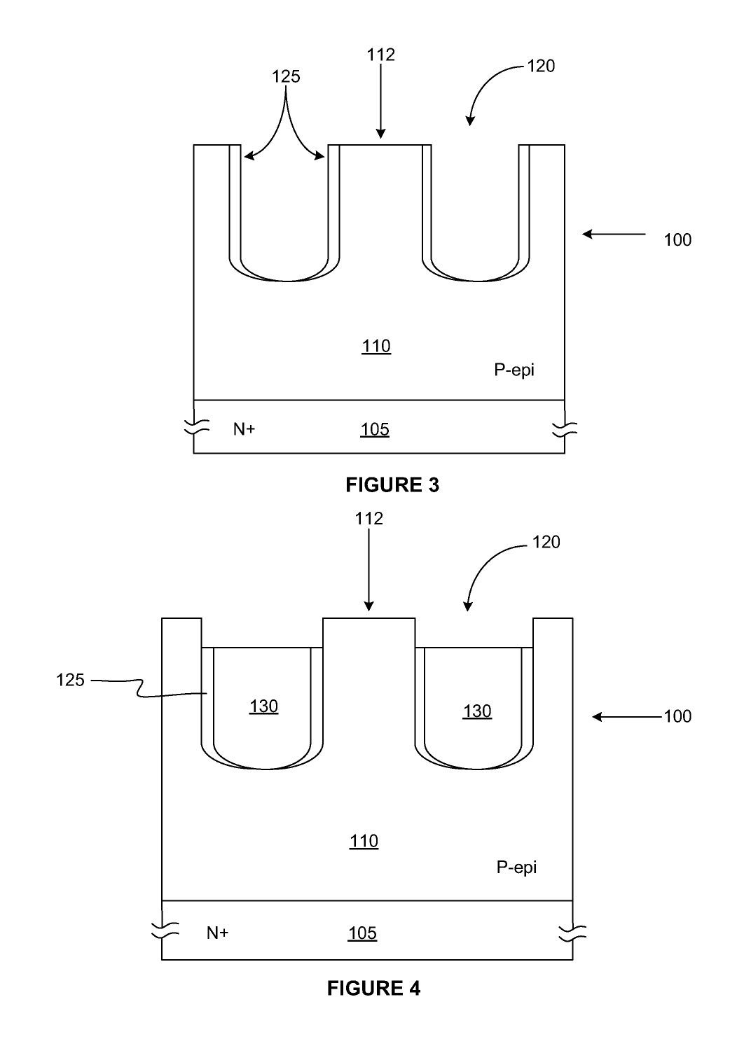

The trench 120 is then created by etching the material of the epitaxial layer 110 (and, if desired, the substrate 105) using any known etchant known in the art. In some embodiments, the epitaxial layer 110 can be etched using any known etchant until the trench 120 has reached the desired depth and width in the epitaxial layer 110. The depth and width of the trench 120, as well as the aspect ratio of the width to the depth, can be controlled so that so a later deposited insulating layer properly fills in the trench and minimizes the formation of voids. In some embodiments, the depth of the trench can range from about 0.1 to about 100 μm. In some embodiments, the width of the trench can range from about 0.1 to about 50 μm. With such depths and widths, the aspect ratio of the trench can range from about 1:1 to about 1:50. In other embodiments, the aspect ratio of the trench can range from about 1:5 to about 1:8.3. After the trench has been created, the mask 115 can be removed from the resulting structure, as shown in FIG. 3. A mesa structure 112 remains between adjacent trenches 120.

Next, as shown in FIG. 3, a gate insulating layer 125 (such as a gate oxide layer) can then be formed on the sidewall and bottom of the trenches 120. The gate insulating layer 125 can be formed by any process known in the art. In some embodiments, the gate insulating layer 125 can be formed by depositing any known insulating material until it overflows the trenches 120. The thickness of the deposited insulating material can be adjusted to any desired thickness. The deposition of the insulating material can be carried out using any known high-quality deposition process, including any chemical vapor deposition (CVD) processes, such as SACVD, which can produce a highly conformal step coverage within the trench. If needed, a reflow process can be used to reflow the deposited insulated material, helping reduce voids or defects within the insulating material. After the insulating layer has been deposited, an etch back process can be used to remove the excess insulating material and form the gate insulating layer 125.

In embodiments where the gate insulating later 125 is a gate oxide layer, the gate oxide layer 125 can be formed by oxidizing the epitaxial layer 110 in an oxide-containing atmosphere until the desired thickness of the oxide layer has been grown in the sidewalls and bottom of the trench 120. In some embodiments, the thickness of the gate oxide layer 125 can range from about 60 Å to about 500 Å.

Then, a conductive layer can be deposited on the gate insulating layer 125 in the trench 120. The conductive layer can comprise any conductive and/or semiconductive material known in the art including any metal, metal alloy, silicide, polysilicon, amorphous silicon, doped polysilicon, or combinations thereof. In some embodiments, the conductive layer comprises a conductive Si material including doped or undoped polysilicon and/or amorphous silicon. The conductive layer can be deposited by any known deposition process, including chemical vapor deposition processes (e.g., CVD, PECVD, or LPCVD) or sputtering processes using the desired metal as the sputtering target. In the embodiments where the conductive layer comprises conductive Si materials, the conductive layer can be deposited using Si-containing gases, such as silane, di-silane, tri-silane, germane, or combinations thereof. The conductive layer can be deposited so that it fills and overflows over the upper part of the trench 120.

Then, a gate conductor 130 (or gate 130) can be formed from this conductive layer using any process known in the art. In some embodiments, as shown in FIG. 4, the gate conductor 130 can be formed by removing the upper portion of the conductive layer using any process known the art, including any etchback process. The result of the removal process also removes the gate insulating layer 125 on the upper portion of trench sidewall, leaving the gate 130 overlying the gate insulating layer 125 formed on the bottom of the trench 120 and sandwiched between the gate insulating layer 125 left on the lower potions of the trench sidewalls, as shown in FIG. 4.

In some configurations of the semiconductor structure 100 shown in FIG. 4, the conductive layer 130 comprises a conductive Si material such as amorphous silicon (A-Si) and/or polysilicon (P—Si). In these configurations, the grains of the hydrophobic silicon material tend to shift away from the hydrophilic silicon oxide material used in the gate oxide layer 125. This movement of the grains can result in formation of voids in those areas which the grains have migrated from, especially at higher temperatures above 900° C. The formation of these voids can result in decreased device performance and reliability because of the deterioration of the electrical conductivity of the gate material in the trench MOSFET.

It has been suggested that this undesired grain movement in the A-Si and/or P—Si material can be stabilized by adjusting the size of the grains. The size of the silicon grains can be increased (or decreased) by increasing (or decreasing) the temperature during formation of the A-Si or P—Si layer. But the ability to adjust the grain size of the Si grains can be constrained by the device characteristics of the semiconductor device. For example, it is difficult to increase the grain size because making the grains larger requires increasing the pitch of the trenches. Yet the the pitch of the trenches keeps diminishing as device dimensions shrink As another example, it can be difficult to decrease the grain size since making the Si grains smaller also makes them less stable as the total free energy is less negative—and therefore less stable—as the radius of the particle decreases.

Adding a nitrogen dopant to the A-Si and/or P—Si material, however, can help stabilize the Si grains by reducing the movement of these grains without modifying the grain size. Thus, in some embodiments, the conductive layer 130 can be formed as a nitrogen-doped A-Si and/or P—Si layer. In other embodiments, the conductive layer 130 can be formed as a nitrogen-doped polysilicon layer. Incorporating the nitrogen atoms into the amorphous silicon or polysilicon material can lower the free energy of the grains, thereby stabilizing the movement of the grain and reducing the formation of voids.

Any amount of nitrogen can be incorporated into the A-Si and/or P—Si layer that lowers the free energy of the silicon grains. In some embodiments, the concentration of nitrogen in the A-Si and/or P—Si layer can range from about 9×10²⁰ to about 4×10²¹ atoms/cm³. In other embodiments, the concentration of N in the A-Si and/or P—Si layer can range from about 9×10²⁰ atoms/cm³ to about 2.8×10²¹ atoms/cm³. In still other embodiments, the concentration can be any suitable combination or sub-range of these amounts.

Adding nitrogen, however, can increase the resistivity of the A-Si and/or P—Si material. To counter this increase in resistivity, the A-Si and/or P—Si layer can also be doped with P- and/or B-containing dopant materials since the P and/or B dopants are able to prevent void formation and movement during thermal cycling. In some embodiments, the concentration of the P and/or B dopants in the A-Si and/or P—Si layer can range from about 1×10¹⁸ atoms/cm³ to about 3×10²⁰ atoms/cm³. In other embodiments, the concentration of the P and/or B dopants in the A-Si and/or P—Si layer can range from about 1×10¹⁹ atoms/cm³ to about 2×10²⁰ atoms/cm³. In still other embodiments, the concentration can be any suitable combination or sub-range of these amounts.

The doped A-Si and/or P—Si layer can be formed using any process known in the art that will give that layer the desired dopant concentrations. In some embodiments, such as where a silane gas is used to form the A-Si and/or P—Si gate, a nitrogen-containing gas can be added to the silane gas. The nitrogen-containing gases that can be added include N₂, NH₃, N₂H₄, HCN, or combinations thereof. These methods can provide a substantially uniform nitrogen concentration along the trench depth which helps prevent void formation and movement during thermal cycling. In other embodiments, though, the nitrogen could be incorporated into the A-Si and/or P—Si layer after the deposition of the A-Si and/or P—Si material in the trench 120 by exposing the A-Si and/or P—Si material to any nitrogen-containing gas(es) described above at elevated temperatures ranging from about 400 to about 650° C.

The P and/or B dopants can be added to the A-Si and/or P—Si layer using any known process that will obtain the concentrations described herein. In some embodiments, such as where silane gas is used to form the A-Si and/or P—Si layer, a P- and/or B-containing gas can be added to the silane gas. The P- and/or B-containing gas(es) that can be used include diborane, PH₃, BCL₃, or combinations thereof. In some other embodiments, the P and/or B dopants can be implanted after the A-Si and/or P—Si material has been formed.

In some embodiments, both the nitrogen-containing gas and the P- and/or B-containing gas can be added at substantially the same time to the silane (or other Si-containing) gas to manufacture the doped A-Si and/or P—Si layer. In some configurations, separate nitrogen-containing gases and P- and/or B-containing gases can be added when depositing the doped A-Si and/or P—Si layer. In other configurations, though, the nitrogen-containing gases and P- and/or B-containing gases can be combined into a single mixture which is then added to the silane gas.

Once incorporated into the conductive Si layer, the dopants in the A-Si and/or P—Si layer can be activated with microwaves at low temperatures. This MW heating process functions to both activate the dopants and recrystallize the A-Si film. In some embodiments, these low temperatures can be less than about 800° C. In other embodiments, these low temperatures can range from about 200 to about 800° C. In yet other embodiments, the temperatures can range from about 200 to about 550° C. In still other embodiments, these low temperatures can be any suitable combination or sub-range of these temperatures. In other embodiments, the MW heating process can be performed as an in-situ process, i.e., when the A-Si and/or P—Si are being deposited and doped.

The microwave heating process can use any frequency or wavelength of microwaves that are allowed for industrial applications by government regulations. In some embodiments, the frequency of the microwaves can range from about 2.45 GHz to about 5.8 GHz and have a wavelength ranging from about 52 mm to about 123 mm. The microwave heating process can be performed for any time sufficient to activate the N and B/P dopants. In some embodiments, the time can range up to about 120 minutes, which is much shorter than the 5 to 6 hours that are often required for conventional furnace processes. In some embodiments, the time can range from about 1 minute to about 120 minutes. In other embodiments, the time can range from about 2 minutes to about 60 minutes. In yet other embodiments, the time can range from about 2 minutes to about 15 minutes. In still other embodiments, the time can be any suitable combination or sub-range of these amounts.

In some embodiments, a combination of rapid thermal processing (RTP) and a MW anneal can be used. In these embodiments, the RTP can be performed from about 900° C. to about 1100° C. for about 30 seconds to about 2 minutes and the MW anneal process can be performed from about 200° C. to about 550° C. for about 30 seconds to about 15 minutes. The combination of RTP and MW heating can be used to both reduce or eliminate voids or seams and lower the sheet resistance of the final trench fill film.

In some embodiments, this MW heating process (whether performed alone or combined with RTP) can provide a low sheet resistance with minimal void formations in the conductive layer 130. The higher temperatures used in other heating processes often create larger voids in the trenches because of the grain movement. But using the MW heating reduces or eliminates these larger voids since the tendency of voids to migrate at lower temperatures is reduced.

In some embodiments, the MW heating process can be used to increase the Si grain size without void migration away from the gate insulating layer 125 since the crystal growth relative to the void migration is accelerated. For example, if an as-deposited silicon film having a sheet resistance of 22.5 ohm/sq. is annealed to 1000° C., the sheet resistance can drop to 12 ohm/sq. Subsequent heating at temperature ranging from 450° C. to 850° C. can raise the sheet resistance due to P atoms precipitating out of the solid grains and into the grain boundaries. The maximum sheet resistance occurs at about 630° C. Above this temperature, the P atoms start dissolving back in the Si gains and the sheet resistance increases, i.e. at 950° C. the sheet resistance can increase to about 13.5 ohm/sq. Repeated anneal cycles exhibit a similar characteristics with the sheet resistance rising due to evaporation of the P atoms. When the A-Si and/or P—Si material is located in a trench, such additional annealing can cause void formation and dramatic increase of the sheet resistance. This void formation may be reduced or eliminated by MW processing at the lower temperatures described herein since it can both activate the dopant and grow the Si grains without the higher temperatures used in standard RTP or furnace processing.

The MW activation process can also reduce or eliminate the seam in the center of the trench that is often formed when the MW activation process is not used. The seam can form when the A-Si and/or P—Si material deposits in the trench since the materials is deposited on the trench sidewall and then grows to the center of the trenach. This seam can be eliminated or reduced since the MW can re-grow the grains.

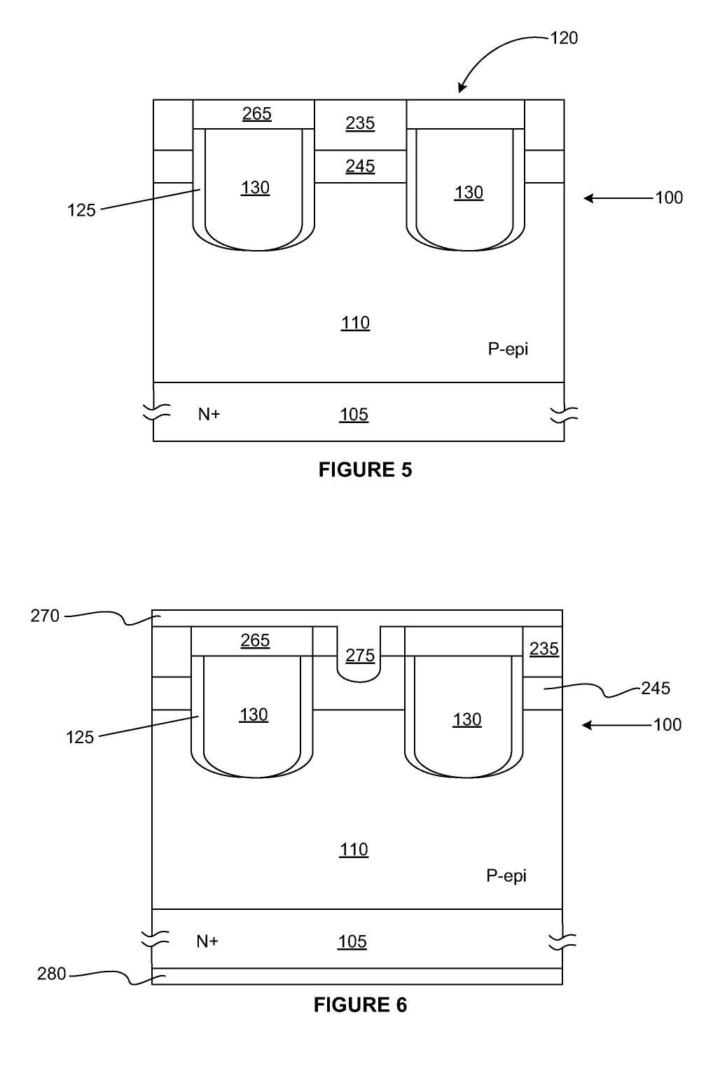

The trench MOSFET structure can then be completed using any process known in the art. In some embodiments, a p-region 245 can be formed in an upper portion of the epitaxial layer 110, as shown in FIG. 5. The p-region can be formed using any process known in the art. In some embodiments, the p-regions regions 245 can be formed by implanting a p-type dopant in the upper surface of the epitaxial layer 110 and then driving-in the dopant using any known process.

Next, a contact region 235 can be formed on the exposed upper surface of the epitaxial layer 110. The contact region 235 can be formed using any process known in the art. In some embodiments, the contact regions 235 can be formed by implanting an n-type dopant in the upper surface of the epitaxial layer 110 and then driving-in the dopant using any known process. The resulting structures after forming the contact region 235 are illustrated in FIG. 5.

Then, the upper surface of the gate 130 is covered with an overlying insulating layer. The overlying insulating layer can be any insulating material known in the art. In some embodiments, the overlying insulating layer comprises any dielectric material containing B and/or P, including BPSG, PSG, or BSG materials. In some embodiments, the overlying insulating layer may be deposited using any CVD process until the desired thickness is obtained. Examples of the CVD processes include PECVD, APCVD, SACVD, LPCVD, HDPCVD, or combinations thereof. When BPSG, PSG, or BSG materials are used in the overlying insulating layer, they can be reflowed.

Then a portion of the overlying insulating layer is removed to leave an insulation cap 265. In the embodiments depicted in FIG. 5, the overlying insulating layer can be removed using any known mask and etching procedure that removes the material in locations other than the gate 130. Thus, an insulating cap 265 is formed over the gate 130. The excess amounts of the overlying insulating layer can be removed using any etch back or planarization process.

Next, as depicted in FIG. 6, the contact region 235 and the p-region 245 can be etched to form an insert region 275. The insert region 275 can be formed using any known masking and etching process until the desired depth (into the p-region 245) is reached. Next, as shown in FIG. 6, a source layer (or region) 270 can be deposited over the upper portions of the insulation cap 265 and the contact region 235. The source layer 270 can comprise any conductive and/or semiconductive material known in the art, including any metal, silicide, polysilicon, or combinations thereof. The source layer 270 can be deposited by any known deposition process, including chemical vapor deposition processes (CVD, PECVD, LPCVD) or sputtering processes using the desired metal as the sputtering target. The source layer 260 will also fill in the insert region 275.

After (or before) the source layer 270 has been formed, a drain 280 can be formed on the backside of the substrate 105 using any process known in the art. In some embodiments, the drain 280 can be formed on the backside by thinning the backside of the substrate 105 using any process known in the art, including a grinding, polishing, or etch processes. Then, a conductive layer can be deposited on the backside of the substrate 105 as known in the art until the desired thickness of the conductive layer of the drain is formed, as shown in FIG. 6.

These doped A-Si and/or P—Si layers and the associated methods for forming them have several desirable features. First, in some configurations they can achieve a low film resistivity in the trench structures which are needed for narrow pitch U-MOS semiconductor devices. This low resistivity can be helpful in achieving a low Rg (gate resistance) and shield gate resistance without using excessive runners which can increase die size and raise wafer cost for a given RDS_{ON}. Second, in some configurations the thermal budget needed when forming a polysilicon gate can be reduced, thereby improving the sheet resistance. Third, in some configurations the thermal stability of a polysilicon gate in a trench isolation device can be enhanced by nitrogen incorporation.

It is understood that all material types provided herein are for illustrative purposes only. Accordingly, while specific dopants are names for the n-type and p-type dopants, any other known n-type and p-type dopants (or combination of such dopants) can be used in the semiconductor devices. As well, although the devices of the invention are described with reference to a particular type of conductivity (P or N), the devices can be configured with a combination of the same type of dopant or can be configured with the opposite type of conductivity (N or P, respectively) by appropriate modifications.

In some embodiments, the semiconductor devices contain a gate trench structure comprising a semiconductor substrate with a trench in an upper portion thereof, a gate insulating layer on the sidewall and bottom of the trench, and a conductive gate comprising an amorphous silicon or polysilicon material on the gate oxide layer, the amorphous silicon or polysilicon material containing a microwave-activated nitrogen dopant concentration and a microwave-activated B or P dopant.

In some embodiments, the semiconductor devices contain a trench MOSFET comprising a semiconductor substrate with a trench in an upper portion thereof, a gate insulating layer on the sidewall and bottom of the trench, and a conductive gate comprising an amorphous silicon or polysilicon material on the gate oxide layer, the amorphous silicon or polysilicon material containing a nitrogen dopant concentration ranging from about 9×10²⁰ atoms/cm³ to about 4×10²¹ atoms/cm³ and a B or P dopant concentration ranging from about 10×10¹⁸ atoms/cm³ to about 2×10²⁰ atoms/cm³.

In addition to any previously indicated modification, numerous other variations and alternative arrangements may be devised by those skilled in the art without departing from the spirit and scope of this description, and appended claims are intended to cover such modifications and arrangements. Thus, while the information has been described above with particularity and detail in connection with what is presently deemed to be the most practical and preferred aspects, it will be apparent to those of ordinary skill in the art that numerous modifications, including, but not limited to, form, function, manner of operation and use may be made without departing from the principles and concepts set forth herein. Also, as used herein, examples are meant to be illustrative only and should not be construed to be limiting in any manner.

1. A method for making a gate trench structure, comprising:
providing a trench in the upper surface of a semiconductor substrate;
forming an insulating layer on the trench sidewall and bottom; and
depositing a doped, conductive Si layer on the insulating layer by heating a Si-containing gas, a N-containing gas, and a B- or P-containing gas; and
activating the deposited Si layer at low temperature using microwaves.

2. The method of claim 1, wherein the insulating layer comprises a gate oxide layer.

3. The method of claim 1, wherein the doped, conductive Si layer comprises amorphous silicon or polysilicon.

4. The method of claim 1, wherein the nitrogen-containing gas comprises N₂, NH₃, N₂H₄, HCN, or combinations thereof.

5. The method of claim 1, wherein the B- or P-containing gas comprises diborane, PH₃, BCL₃, or combinations thereof.

6. The method of claim 1, wherein the low temperature of the activation process is less than about 800° C.

7. The method of claim 1, wherein the low temperature of the activation process ranges from about 200° C. to about 550° C.

8. The method of claim 1, wherein the deposition process yields a nitrogen dopant concentration ranging from about 9×10²⁰ atoms/cm³ to about 4×10²¹ atoms/cm³.

9. The method of claim 1, wherein the deposition process yields a B dopant concentration ranging from about 10×10¹⁸ atoms/cm³ to about 2×10²⁰ atoms/cm³.

10. The method of claim 1, wherein the deposition process yields a P dopant concentration ranging from about 10×10¹⁸ atoms/cm³ to about 2×10²⁰ atoms/cm³.

11. A method for making a trench MOSFET structure, comprising:
providing a trench in the upper surface of a semiconductor substrate;
forming a gate insulating layer on the trench sidewall and bottom; and
forming a doped, conductive Si gate on the gate insulating layer by heating a Si-containing gas, a N-containing gas, and a B- or P-containing gas;
activating the conductive Si gate at low temperature using microwaves;
forming an insulating layer over the conductive Si gate; and
forming a source and a drain.

12. The method of claim 11, wherein the gate insulating layer comprises a gate oxide layer.

13. The method of claim 11, wherein the doped, conductive Si layer comprises amorphous silicon or polysilicon.

14. The method of claim 11, wherein the nitrogen-containing gas comprises N₂, NH₃, N₂H₄, HCN, or combinations thereof.

15. The method of claim 11, wherein the B- or P-containing gas comprises diborane, PH₃, BCL₃, or combinations thereof.

16. The method of claim 11, wherein the low temperature of the activation process is less than about 800° C.

17. The method of claim 11, wherein the low temperature of the activation process ranges from about 200° C. to about 550° C.

18. (canceled)

19. (canceled)

20. (canceled)

21. A method for making a gate trench structure, comprising:
providing a trench in the upper surface of a Si substrate;
forming a gate oxide layer on the trench sidewall and bottom; and
forming a conductive Si gate on the gate oxide layer, the gate having a N dopant concentration ranging from about 9×10²⁰ atoms/cm³ to about 4×10²¹ atoms/cm³ and a P or B dopant concentration ranging from about 10×10¹⁸ atoms/cm³ to about 2×10²⁰ atoms/cm³; and
activating the conductive Si gate using microwaves at a temperature less than about 800° C.

22. The method of claim 21, wherein the conductive Si gate comprises amorphous silicon or polysilicon.

23. The method of claim 21, wherein the low temperature of the activation process ranges from about 200° C. to about 550° C.
